(19) United States
(12) Patent Application Publication
(10) Pub. No.: US 2026/0239715 A1
(43) Pub. Date: Aug. 13, 2026

(54) SEMICONDUCTOR DEVICE METALLIZATION STRUCTURE FOR RELIABILITY AND ROBUSTNESS

(71) Applicant: SEMICONDUCTOR COMPONENTS INDUSTRIES, LLC, Scottsdale, AZ (US)

(72) Inventors: Mingjiao LIU, Gilbert, AZ (US); Prasad VENKATRAMAN, Gilbert, AZ (US); Jin-Myung KIM, Bucheon (KR)

(73) Assignee: SEMICONDUCTOR COMPONENTS INDUSTRIES, LLC, Scottsdale, AZ (US)

(21) Appl. No.: 19/048,054

(22) Filed: Feb. 7, 2025

(51) Int. Cl. H10D 64/66; H10D 12/00; H10D 12/01; H10D 62/10

(52) U.S. Cl. CPC H10D 64/666; H10D 12/031; H10D 12/415; H10D 62/102; H10D 64/661

(57) ABSTRACT

A semiconductor device includes a semiconductor substrate. A first metal layer having a first thickness is disposed on a first portion of a surface of the semiconductor substrate. A second metal layer having a second thickness is disposed on a second portion of the surface of the semiconductor substrate. The first thickness is greater than the second thickness. A passivating dielectric material layer is disposed over both the first metal layer and the second metal layer.

### TECHNICAL FIELD

This description relates to metallization schemes for semiconductor devices and integrated circuits.

### BACKGROUND

Semiconductor devices fabricated, for example, on a semiconductor die or wafer, employ metallization primarily to serve as a means of wiring for electrical contact and interconnection within the circuits and device components in the die. After the devices have been fabricated in the semiconductor wafer, connections must be made to link the circuits or device components together. This process is called metallization. Metal layers are deposited on the wafer to form conductive pathways between the circuits or device components. Typically, a passivating material layer (e.g., a dielectric material layer) is deposited on a metal layer (e.g., on a top surface of a semiconductor device) not only to protect the device mechanically, but also to chemically and electrically stabilize the exposed surfaces of the semiconductor device. Cracks in the passivating layer can have a deleterious effect on the semiconductor device performance and degrade reliability and robustness of the device.

### SUMMARY

In a general aspect, a semiconductor device includes a semiconductor substrate. A first metal layer having a first thickness is disposed on a first portion of a surface of the semiconductor substrate. A second metal layer having a second thickness is disposed on a second portion of the surface of the semiconductor substrate, The first thickness is greater than the second thickness. The semiconductor device further includes a passivating dielectric material layer disposed over both the first metal layer and the second metal layer.

In a general aspect, a method includes depositing metal layers including a barrier metal layer and a top metal layer on a surface of an insulated-gate bipolar junction transistor (IGBT) device. The method further includes patterning and etching the top metal layer to form a thick metal layer. The method further includes patterning and etching the metal layers to form a thin metal layer, and depositing a passivating material layer on both the thick metal layer and the thin metal layer.

In a general aspect, a method includes depositing a barrier metal layer on a surface of an insulated-gate bipolar junction transistor (IGBT) device, and patterning and etching the barrier metal layer to form thin metal layers. The method further includes depositing a top metal layer on a top surface of the IGBT device, and patterning and etching the top metal layer to form a thick metal layer in portions of the surface and expose the thin metal layers in other portions of the surface. The method further includes depositing a passivating material layer on both the thick metal layer and the thin metal layers.

In a general aspect, a method includes depositing a barrier metal layer followed by a top metal layer on a top surface of a device, and a first patterning and a first metal etching of the top metal layer and the barrier metal layer to form at least one thick metal layer structure. The at least one thick metal layer structure includes a segment of the top metal layer disposed on a segment of the barrier metal layer. The method further includes a second photolithographic patterning and a second metal etching of the top metal layer to form at least one thin metal structure. The at least one thin metal structure. includes a segment of the barrier metal layer disposed on the top surface of the device. The method further includes depositing a passivating material layer on both the thick metal structure(s) and the thin metal structure(s).

The details of one or more implementations are set forth in the accompanying drawings and the description below. Other features will be apparent from the description and drawings, and from the claims.

### BRIEF DESCRIPTION OF THE DRAWINGS

FIG. 1 is a schematic cross-sectional view of a metallization structure extending across a semiconductor device surface and including metal layers of different thicknesses in different regions of the device surface.

FIG. 2 illustrates a partial cross-sectional view of a device having a metallization structure disposed on a top surface of the device.

FIG. 3 illustrates a metallization structure that involves two different types of passivating layers disposed on a top surface of a device (e.g., the IGBT device of FIG. 2).

FIG. 4 illustrates an example method for fabricating the metallization structure on the device of FIG. 2.

FIGS. 5A through 5D illustrate cross-sectional views of a metallization structure on a device at various stages of construction.

FIG. 6 illustrates another example method for fabricating the metallization structure on the device of FIG. 2.

FIG. 7 illustrates yet another example method for fabricating the metallization structure on the device of FIG. 2.

In the drawings, which are not necessarily drawn to scale, like reference symbols or alpha numerals may indicate like and/or similar components in different views. The drawings illustrate, by way of example, but not by way of limitation, various implementations discussed in the present disclosure. Reference symbols or alpha-numeral identifiers shown in one drawing may not be repeated for the same, and/or similar elements in related views. Reference symbols or alpha-numeral identifiers that are repeated in multiple drawings may not be specifically discussed with respect to each of those drawings but are provided for context between related views. Also, not all like elements in the drawings are specifically referenced with a reference symbol or an alpha-numeral identifier when multiple instances of an element are illustrated.

### DETAILED DESCRIPTION

Conductive metal or metallic material can be used to form the gates in a semiconductor device or integrated circuit (IC) (e.g., a field effect transistors (FET)). Conductive metal or metallic material layers can also be used to provide electrical interconnections at different metallization levels within the semiconductor device or IC, and to form device contact areas (such as for ohmic contacts or Schottky barrier contacts). Desired properties of the metal layers or metallization layers for integrated circuits include low resistivity; ease of formation, ease of etching for pattern generation, mechanical stability, good adherence, and low stress, etc. A metallization layer can further be passivated. Passivation involves the creation of an outer layer of shielding material (e.g., dielectric material) in the semiconductor devices. The outer layer of passivation material may be applied as a micro coating on the metallization layers to reduce environmental effects on the metallization layers. The passivation layers can be organic or inorganic in nature.

The passivation layers applied over the metallization layers in semiconductor devices or ICs are prone to cracking due to, for example, thermal cycling. The cracking can lead to moisture ingress into the device circuits and cause corrosion. The issue can be more acute for a high aspect ratio metallization layer (e.g., a thick top metallization layer) where a stress intensity factor (SIF) is higher. Standard design passivation layers on a thick (e.g., >2000 nm or >3000 nm) top metallization layer may be susceptible to cracking due to thermal stress. In an example implementation, a traditional high power semiconductor device may, for example, be a 1200V insulated-gate bipolar transistor (IGBT) or fast recovery diode (FRD). The device may have a 5 μm thick gate (or emitter) metal layer made, for example, of aluminum copper (AlCu), and a 1.5 um thick passivating layer made, for example, of a high refractive index nitride (HRN) material, applied over the metal layer. The HRN layer may be applied over a step at an end of the metal layer. The passivation layer in such a traditional device is prone to cracking at the step of the passivation layer over the end of the metal layer. The concepts described herein are related to a reliable and robust metallization scheme that can include metal layer layouts and/or passivation layers that are not prone to cracking.

Devices that can benefit from the reliable and robust metallization structures disclosed herein include, for example, high voltage power devices such as a high voltage IGBTs, FRDs, and so forth. A high voltage IGBT is a key component in nearly all medium to high power electronic system applications including industrial drives, UPS, renewables, electric cars and traction, etc. The reliability of the high voltage power device (e.g., IGBT and FRD) is critical to these applications. For commercial applications, the high voltage device should pass one or more standardized tests for the reliability of the passivation layer used to protect the metallization layer. The reliability tests may include, for example, a High Temperature Reverse Bias Test (HTRB), a High Humidity, High Temperature and High Voltage Reverse Bias Test (H3TRB), a High-Voltage Temperature Humidity Bias Test (HV-HTB), a Highly Accelerated Temperature/Humidity Stress Test (HAST), etc.

A thickness of a metallization layer (in other words, a metal layer) in a high power semiconductor device (e.g., an IGBT or an FRD) may be based, for example, on the requirements of a current load in the device. An example, high power semiconductor device (e.g., an IGBT or FRD) have a thick metal layer (e.g., greater than 2 μm thick) as a gate metallization layer (or as an emitter electrode metal layer).

The present disclosure presents a reliable and robust metallization scheme, for example high voltage power devices (e.g., an IGBT or an FRD). The disclosed metallization scheme includes a layout of metal layer segments at a gate metallization level of a device (e.g., an IGBT). The metal layer segments may be embedded in interlayer dielectric (ILD) layers in a multilayered structure. An ILD layer may serve as an insulating layer between different conducting layers to prevent interference and short circuits. In example implementations, the metal layer segments may have different respective gauges or thicknesses and can be covered by a passivating dielectric overlayer that is not prone to cracking. At least some of the metals that can be used for the metal layer segments can include aluminum, nickel, chromium, gold, germanium, copper, silver, titanium, tungsten, platinum, and tantalum. Selected metal alloys or other conductive material (e.g. doped polysilicon) may also be used.

In the disclosed metallization scheme for an example IGBT device, the gate metallization level of the device may include metal layer segments disposed on the surface of the device. The segments may, for example, include an emitter metal layer segment, a gate runner metal layer segment, and a termination region metal layer segment. In some implementations, the respective metal layer segments may be metal layers of different gauges (i.e., thickness) disposed on the surface of the device. In some implementations, a combination of robust termination metal layers and/or a right passivation material (e.g. a high refractive index nitride (HRN) material) can be used for fabricating a passivation layer over the metal layers that is not prone to cracking due to, for example, thermal stress.

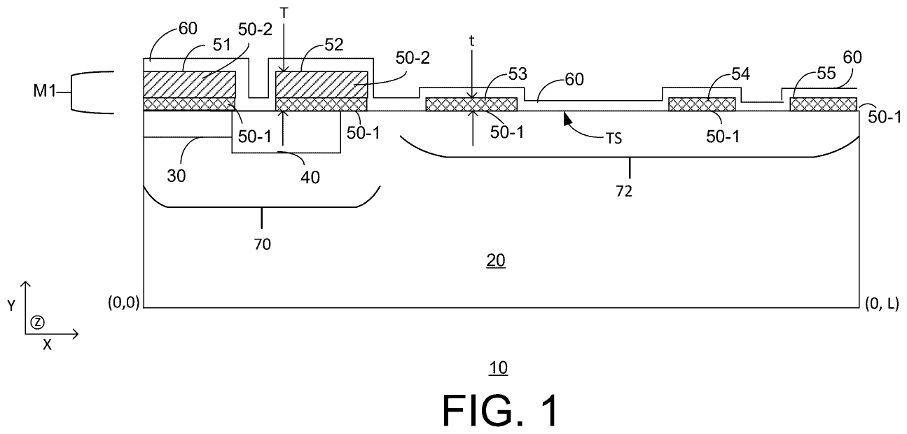

FIG. 1 is a schematic illustration of a metallization structure including a plurality of metal layer segments extending across a semiconductor device surface. Different metal layer segments in different portions of the device surface can have different thicknesses.

FIG. 1 shows, for example, a cross-sectional schematic view of one half of an IGBT device 10 fabricated in a semiconductor substrate 20 having a top surface TS. FIG. 1 shows, for example, a cross-sectional view of one half of the device extending in an x-y plane between co-ordinates (0, x=0) and (0, x=L). In example implementations, IGBT device 10 may be symmetric (full device not shown) about the y axis at x=0.

Semiconductor substrate 20 may include various device elements of IGBT device 10 (e.g., a gate region 30, an emitter region 40) in an active region 70 on or below the top surface TS. A junction termination region 72 may surround, or be adjacent, to active region 70 on the top surface TS on semiconductor substrate 20.

A metallization structure M1 may be disposed on top surface TS of the semiconductor substrate. Metallization structure M1 may include first metal layer segments (e.g., metal layer segment 51, metal layer segment 52, etc.) disposed, for example, on gate region 30 and emitter region 40, respectively, and one or more second metal layer segments (e.g., metal layer segment 53, metal layer segment 54, metal layer segment 55, etc.) disposed on top surface TS in junction termination region 72. The second metal layer segments (e.g., metal layer segments 53, 54, 55) may be made of a metal layer 50-1 having a thickness “t”. In example implementations, metal layer 50-1 may include seed or barrier metal layers. The seed or barrier metal layer may be made, for example, of include layers of titanium (Ti), titanium nitride (TiN) and or tungsten (W). In example implementations, the seed or barrier metal layer (metal layer 50-1) may be less than 1.0 μm in thickness.

The first metal layer segments (e.g., metal layer segment 51, metal layer segment 52, etc.) may include a second metal layer 50-2 disposed on top of metal layer 50-1 corresponding to the second metal layer segments (e.g., metal layer segments 53, 54, 55). In example implementations, second metal layer 50-2 may be made of one or more of aluminum (Al), aluminum silicon (AlSi), copper (Cu), and copper silicon (CuSi). In example implementations, the second metal layer (metal layer 50-2) may be 1.0 μm or greater than 1.0 μm in thickness.

The Ti layer in the underlying seed or barrier metal layer (metal layer 50-1) may serve as an etch stop layer for etchants that may be used to etch the overlying second metal layer 50-2 (e.g., made of Al, AlSi, Cu, CuSi, etc.).

The first metal layer segments (e.g., metal layer segment 51, metal layer segment 52, etc.) may have a thickness T which is greater than the thickness t of the second metal layer segments (e.g., metal layer segments 53, 54, 55). In example implementation, the thickness t of the second metal layer segments may be less than about 0.5 μm. The thickness T of the first metal layer segments (e.g., metal layer segments 51, and 52) may be 2 μm or greater.

A passivation layer (e.g., layer 60) may cover the first metal layer segments (e.g., metal layer segment 51, metal layer segment 52, etc.) and the second metal layer segments (e.g., metal layer segments 53, 54, 55) on top surface TS. In example implementations, layer 60 may be a dielectric material (e.g., an oxide, a nitride, or a high refractive index nitride (HRN), etc.).

The difference in thickness (height) between the first metal layer segments (e.g., metal layer segment 51, metal layer segment 52, etc.) and the second metal layer segments (e.g., metal layer segments 53, 54, 55) and the choice of dielectric material (e.g., HRN) for layer 60 can result in a passivating layer (layer 60) over metallization structure M1 that is not prone to cracking.

It will be noted that FIG. 1, for visual clarity, does not show other passivation layers (e.g., oxide or other dielectric layers) that may be disposed on top surface TS underneath the metal layer 50-1.

In example implementations, for a high voltage IGBT device, the first metal layer segments (e.g., metal layer segment 51, metal layer segment 52, etc.) disposed on gate region 30 and emitter region 40 may be thick metal layers with thicknesses T, for example, between 0.5 and 7 μm (e.g., 5 μm) and the second metal layers (e.g., metal layer segments 53, 54, 55) disposed on junction termination region 72 may be a thinner metal layers with a thickness, for example, between 0.2 and 0.5 μm (e.g., 0.3 μm). The passivating dielectric overlayer (e.g., a HRN layer) is applied over both thick and thin metal layers (in other words, over the thick first metal layer segments (e.g., metal layer segment 51, metal layer segment 52, etc.) disposed on gate region 30 and emitter region 40, and over the thin second metal layer segments (e.g., metal layer segments 53, 54, 55) disposed over junction termination region 72).

In some example implementations, the first metal layer segments may be coupled to an emitter and/or a gate of the device. In some example implementations, a first metal layer segment (e.g., metal layer segment 51) that is shown in FIG. 1 as being disposed on gate region 30 may form a gate electrode and/or emitter electrode of the device. Another first metal layer segment (e.g., metal layer segment 52) that is shown in FIG. 1 as being disposed on emitter region 40 may form a gate runner electrode of the device.

When viewed in two dimensions (e.g., in the −y direction), the gate runner electrode (metal layer segment 52) may form a ring (not shown in the view of FIG. 1) that either fully or partially encircles gate region 30 in the x-z plane on the top surface TS of the device. In some example implementations, the gate runner electrode (e.g., metal layer segment 52) may be in physical contact with a physical gate material (e.g., gate polysilicon (gate poly)) (not shown) of the gate, which may extend across the surface of the device die. The gate runner electrode, which may encircle the physical gate, is the metal layer segment that delivers gate current to the physical gate distributed across the surface of the die with local contacts (not shown) at several points to the gate poly along the length of the gate runner.

In example implementations, the second metal layer segments (e.g., metal layer segments 53, 54, 55) disposed over junction termination region 72 may include surface field or potential plates (or rings) that may be combined with, for example, oxide/polysilicon-filled trenches, and/or buried p-doped rings to obtain an improved distribution of potential field lines in the junction termination region 72 of the IGBT device. In example implementations, for example, metal layer segment 53 may form a floating potential plate and metal layer segment 54 may form a fixed potential plate on surface TS of the device). Further, for example, metal layer segment 55 may form a channel stopper configured to limit the spread of a channel area (e.g., in the x direction) or to prevent the formation of parasitic channels under surface TS in junction termination region 72.

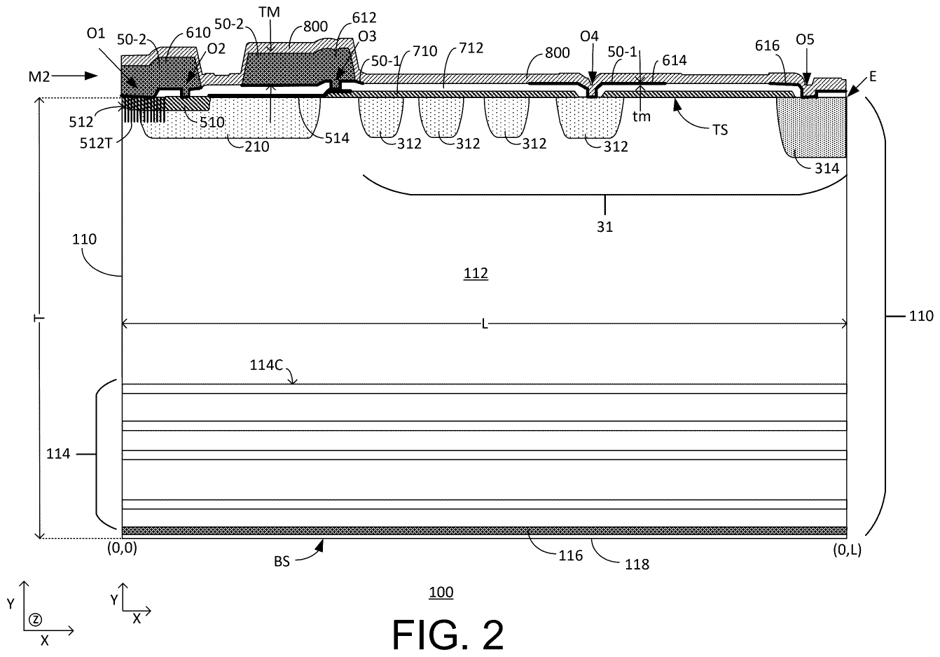

More details about these various implementations of the above metallization structure are described in detail below in connection with at least FIGS. 2 through 5.

FIG. 2 illustrates a partial cross-sectional view of an IGBT device (e.g., device 100) having a metallization structure M2 disposed on a top surface of the device. Device 100 may, for example, be a trench-gate IGBT. Device 100 may have a width 2*L (in the x-direction), but only one half of the device (i.e., the right half of the device from co-ordinate (0,0) to (0, L)) is represented in the cross-sectional view (in the x-y plane) shown in FIG. 2. In example implementations, as discussed below, metallization structure M2 may, for example, include a metal layer segment (e.g., metal layer 610) serving as an emitter and/or gate electrode, a metal layer segment (e.g., metal layer 612) serving as a gate runner metal layer, a metal layer segment (e.g., metal layer 614) forming a field potential plate, and a metal layer segment (e.g., metal layer 616) forming a channel stop, etc.,

The device structures (e.g., insulated gate, bipolar transistor, etc.) of device 100 may be fabricated in a semiconductor substrate 110 having a thickness or height T between a top surface TS and a bottom surface BS. Semiconductor substrate 110 may include a body 112 that is n doped. The n doping level in body 112 may gradually increase in a region 114 at the bottom semiconductor substrate (e.g., semiconductor substrate 110) to an n+doping level. The increasing n+doping levels in region 114 are schematically represented in FIG. 2 by dopant concentration contour lines 114C.

A p+ doped semiconductor layer 116 in ohmic contact with a metal layer 118 disposed at the bottom of semiconductor substrate 110 may form the collector of the bipolar transistor in device 100. In example implementation, semiconductor substrate 110 may, for example, be a silicon, a silicon carbide, a germanium, a gallium arsenide or other type of semiconductor substrate.

The device structures of device 100 (e.g., an IGBT device) may, for example, include a trench capacitor 512, and a p+ doped region 510 disposed in a p-doped well 210 at top surface TS. The p+ doped region may for example, serve as an emitter of the bipolar transistor.

Portions of the surface of top surface TS of device 100 (e.g., an IGBT) may be coated with insulating layers (e.g., a first dielectric layer 710 and a second dielectric layer 712). First dielectric layer 710, may, for example, be an oxide glass film doped with phosphorus and or boron (PSG/BPSG). Second dielectric layer 712 may for example, be a silicon dioxide film. Openings (e.g., opening O1, O2, O3, O4, and O5, etc.) in the first dielectric layer 710 and the second dielectric layer 712 may expose portions of the surface the semiconductor substrate. Elements of metallization structure M2 disposed on the top surface of device 100 may be in contact with the device structures of device 100 formed in the semiconductor substrate through these openings (e.g., opening O1, O2, O3, O4, and O5, etc.)

A metal layer segment (e.g., metal layer 610) of metallization structure M2 disposed above trench capacitor 512 and p+ doped region 510 may serve as an emitter and/or insulated gate electrode of the device. Metal layer 610 may include a top metal layer (e.g., layer 50-2, FIG. 1) having a thickness TM disposed on a bottom or a seed or barrier metal layer (e.g. layer 50-1, FIG. 1) having a thickness tm.

In example implementations, trench capacitor 512 may include several vertical trenches lined with gate oxide (not shown) and filled with gate poly. In example implementations, a width of a trench 512T in trench capacitor 512 may be only 1-2 μm, and trench 512T may be 4 μm to 5 μm deep or even deeper. Trench capacitor 512 may form a gate of device 100.

A strip of gate poly 514 may connect the p+ doped region 510 to a gate runner (e.g., metal layer 612) in metallization structure M). The gate runner metal layer (e.g., metal layer 612), like metal layer 610, may include a top metal layer (e.g., layer 50-2, FIG. 1) having a thickness TM disposed on a bottom or a seed or barrier metal layer (e.g., layer 50-1, FIG. 1) having thickness tm.

Further in device 100, a junction termination region 31 may include a plurality of p doped wells (e.g., p-well 312) and a n++ doped well 314 buried under top surface TS. The n++ doped well 314 may be disposed at an outer edge E of device 100.

A metal layer (e.g., metal layer 614) disposed above and in contact with a p doped well under the surface TS may form a field potential plate for maintaining potentials across surface TS. Metal layer 614 may be formed by a bottom metal layer (e.g., a seed or barrier metal layer) (e.g., layer 50-1, FIG. 1) having thickness tm. In the example shown in FIG. 2, metal layer 614 is in contact with only one of the four p-wells (e.g., p-well 312) (i.e., the outermost p-well shown in FIG. 1) to form a potential field plate having a potential value corresponding to the potential value of the contacted p-well. In other example implementations, other or additional potential field plates may be formed by metal layers contacting the other or additional p-wells. In some example implementations, a metal layer (e.g., metal layer 614) forming a field plate may not directly contact, but may be capacitively coupled to, p-well 312.

Further, a metal layer (e.g., metal layer 616) disposed above and in contact with the n++ well 314 under the surface TS at the edge of the device may form a channel stopper configured to limit the spread of a channel area or to prevent the formation of parasitic channels under surface TS in junction termination region 31. Metal layer 616 may be formed by the bottom or a seed or barrier metal layer (e.g. layer 50-1, FIG. 1) having thickness tm.

As further shown in FIG. 2 (and as noted above) in the disclosed metallization schemes, metallization structure M2 may include a first dielectric layer FI\hat{ }. 6 (e.g., an oxide glass film doped with phosphorus and or boron (PSG/BPSG)) and a second dielectric layer 712 (e.g., a silicon dioxide film) disposed consecutively (one above the other) on portions of the top surface TS to protect the device structures in semiconductor substrate 110. A strip of gate poly 514 may be disposed on a portion of top surface TS and may extend over an edge of first dielectric layer 710. The second dielectric layer 712 may extend over a portion of the strip of gate poly 514.

First dielectric layer 710 and a second dielectric layer 712 may be patterned and etched to from openings (e.g., opening O1, O2, O3, O4, and O5, etc.) that can provide access to the underlying device features (e.g., strip of gate poly 514, p+ doped region 510, one or more of the plurality of p doped wells (e.g., p-well 312) and a n++ doped well 314 buried under top surface TS. Metal layers (e.g., metal layer 610, metal layer 612, metal layer 614, metal layer 616, etc.) formed on or above the first and or second dielectric layers may contact the underlying device features through these openings (e.g., opening O1, O2, O3, O4, and O5, etc.).

In example implementations, the metal layers of metallization structure M2 may include an emitter metal layer (e.g., metal layer 610), a gate runner metal layer (e.g., metal layer 612), and junction termination region metal layers (e.g., metal layer 614 and metal layer 616. Metal layer 610 may serve as an emitter electrode (and may also function as gate electrode). Metal layer 612 may serve as a gate runner electrode. In example implementations, the emitter metal layer (metal layer 610) and the gate runner metal layer (metal layer 612) may have about a same vertical thickness (e.g., thickness TM) (in the Y direction). Metal layer 614 and metal layer 616 in the junction termination region may have a thickness tm that is less than TM. In example implementations, thickness TM may be between about 2 μm and 10 μm (e.g., 5 μm); and thickness tm may be less than 0.5 μm (e.g., 0.3 μm).

In example implementations, the metal layers of metallization structure M2 may include a seed or barrier metal layer and a top metal layer. The seed or barrier metal layer may be made, for example, of layers of titanium (Ti), titanium nitride (TiN) and tungsten (W). The top metal layer may be a layer of a metal or a metal alloy that can be selectively etched relative to the seed or barrier metal layer. In example implementations, the top metal layer may be a layer of metal or metal alloys (e.g., aluminum-silicon (AlSi), aluminum-copper (AlCu), aluminum-silicon-copper (AlSiCu), etc.) that can be etched, for example, by a wet etchant (e.g., an acid). The seed or barrier metal may be comparatively resistant to being etched by the wet etchant.

In an example implementation, the metal layers of small thickness (e.g., with tm less than 0.5 μm) such as metal layer 614 in junction termination region 31 may exclude the top metal layer and be made entirely of the barrier metal layer (e.g. Ti/TiN/W). The metal layers of larger thickness (e.g., with TM~2 to 12 μm) (such as metal layer 610 and metal layer 612) may include the top metal layer made of AlSi, AlCu, or AlSiCu deposited above the barrier metal layer (e.g. Ti/TiN/W).

In metallization structure M2, a passivating dielectric layer (e.g., dielectric layer 800) may be disposed on both the thicker metal layers (e.g., emitter metal layer (metal layer 610) and gate runner metal layer (metal layer 612) and the thinner metal layers (e.g., junction termination region metal layers (metal layer 614 and metal layer 616). The passivating dielectric layer may, for example, be a silicon oxide layer or a high refractive index silicon nitride (HRN) layer.

A combination of dual gauge metal layer segments (i.e., metal segments of thickness TM and metal segments of thickness tm) in metallization structure M2 and a choice of a right passivation material (e.g., a high refractive index nitride (HRN) material) may result in a passivation layer (e.g., dielectric layer 800) over the metal layers that is not prone to cracking.

The thin metal layers (e.g., metal layer 614 and metal layer 616) made of Ti/TiN/W and having a thickness less than 0.5 μm provide a field or potential junction termination region 31 for the device. No aluminum is included in the metal layer segments extending to the edges of the IGBT device (e.g., above n++ doped well 314, FIG. 2). The absence of aluminum at the edges of the device increases the corrosion resistance of the device compared to devices in which aluminum is present at the edges.

An IGBT device can be the combination of a bipolar junction transistor (BJT) and a metal-oxide-semiconductor field-effect transistor (MOSFET). Its name also implies the fusion between them. “Insulated Gate” refers to the input part of MOSFET having very high input impedance. It does not draw any input current, rather it operates on the voltage at its gate terminal. “Bipolar” refers to the output part of the BJT having bipolar nature where the current flow is due to both types of charge carriers.

In some example implementations, robust and reliable metallization structures can involve using diverse types of passivating layers for the thin and the thick metal layers. One type of passivating layer (e.g., an HRN layer) can be used for passivating thin metal layers and another type of passivating layer (e.g., a polyimide film) may be used to passivate thick metal layers.

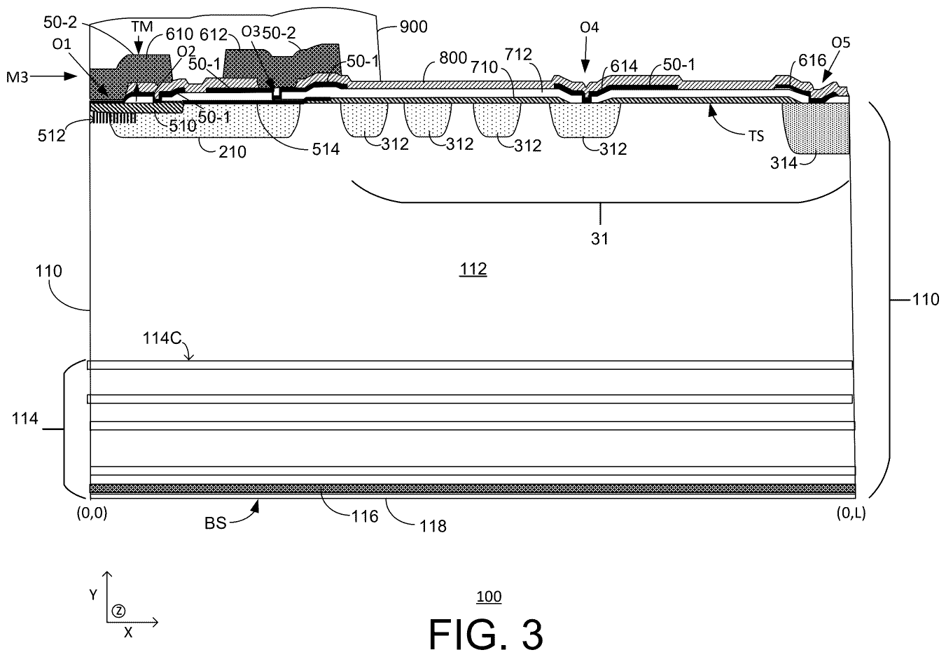

FIG. 3 illustrates a metallization structure M3 that involves two different types of passivating layers disposed on a top surface of a device (e.g., device 100, FIG. 2). Like FIG. 2, FIG. 3 shows a partial cross-sectional view of device 100 (FIG. 2). Only one half of the device (i.e., the right half of the device from co-ordinate (0,0) to (0, L)) is represented in the cross-sectional view (in the x-y plane) shown in FIG. 3. Metallization structure M3 is disposed on top surface TS of the device.

In example implementations, as discussed below, metallization structure M3 may, for example, include a metal layer segment (e.g., metal layer 610) serving as an emitter and/or gate electrode, a metal layer segment (e.g., metal layer 612) serving as a gate runner electrode, metal layer segment (e.g., metal layer 614) forming a field potential plate, and a metal layer segment (e.g., metal layer 616) forming a channel stop, etc.,

As further shown in FIG. 3 metallization structure M3 may include a first dielectric layer 710 (e.g., an oxide glass film doped with phosphorus and or boron (PSG/BPSG)) and a second dielectric layer 712 (e.g., a silicon dioxide film) disposed consecutively (one above the other) on portions of the top surface TS to protect the device structures in semiconductor substrate 110. A strip of gate poly 514 may be disposed on a portion of top surface TS and may extend over an edge of first dielectric layer 710. The second dielectric layer 712 may extend over a portion of the strip of gate poly 514.

First dielectric layer 710 and a second dielectric layer 712 may be patterned and etched to from openings (e.g., opening O1, O2, O3, O4, and O5, etc.) that can provide access to the underlying device features (e.g., strip of gate poly 514, p+ doped region 510, one or more of the plurality of p doped wells (e.g., p-well 312) and a n++ doped well 314 buried under top surface TS.

Initially, a thin metal layer (e.g., layer 50-01 of thickness tm) is disposed on first dielectric layer 710 and may contact the underlying device features through these openings (e.g., opening O1, O2, O3, O4, and O5, etc.). The thin metal layer (e.g., layer 50-01) may, for example, be made of Ti/TiN/W and have a thickness less than 0.5 μm. The thin metal layers (e.g., layer 50-01) in the junction termination region 31 (on the right side of the FIG. 3) may correspond to a metal layer segment (e.g., metal layer 614) forming a field potential plate, and a metal layer segment (e.g., metal layer 616) forming a channel stop.

In metallization structure M3, a passivating dielectric layer (dielectric layer 800) may initially be disposed on the thin metal layer 50-1 across the width of the device. The passivating dielectric layer may, for example, be a silicon oxide layer or a high refractive index silicon nitride (HRN) layer. Portions of the dielectric layer 800 may be removed to expose metal layer 50-1, for example, over openings O1, O2 and O3. Further portions of the dielectric layer 800 may be removed between a length between opening O2 and O3, between opening O3 and the metal layer segment (e.g., metal layer 614) forming the field potential plate, and between the field potential plate and the metal layer segment (e.g., metal layer 616) forming the channel stop. Thick metal layer segments (e.g., metal layer 50-2) may be further disposed over opening O1 and opening O2 to contact the underlying thin metal layers 50-1 to form the thick metal layer (e.g., metal layer 610) serving as an emitter and/or gate electrode, and to form the thick metal layer (e.g., metal layer 612) serving as the gate runner. Metal layer 610) and metal layer 612 may have a thickness TM

As shown on the left side of FIG. 3, a portion of metal layer 50-1 disposed under a thick metal layer 50-2 may be a part of a thick metal layer segment (e.g., metal layer 610) serving as an emitter and/or gate electrode. Further, a portion of metal layer 50-1 disposed under a thick metal layer 50-2 may be a part of a segment of a thick metal layer (e.g., metal layer 612) serving as a gate runner electrode.

In metallization structure M3, as shown in FIG. 3, a passivating dielectric layer 900 (e.g., a polyimide material) may be disposed only on the thick metal layer (e.g., metal layer 610) serving as an emitter and/or gate electrode, and the thick metal layer (e.g., metal layer 612) serving as the gate runner. The polyimide material is not disposed over the exposed thin metal layers, i.e., the thin metal layer segment (e.g., metal layer 614) forming the field potential plate, and the thin metal layer segment (e.g., metal layer 616) forming the channel stop. The passivating dielectric layer (e.g., a silicon oxide layer or the high refractive index silicon nitride (HRN) layer) continues to protect the thin metal layer segment (e.g., metal layer 614) forming the field potential plate, and the thin metal layer segment (e.g., metal layer 616) forming the channel stop.

In example implementations, the metal layers (e.g., layer 50-1 and layer 50-2) of different gauge (thickness) and the passivation layers in metallization structures M1, M2 and M3 may be fabricated using wafer-level processes.

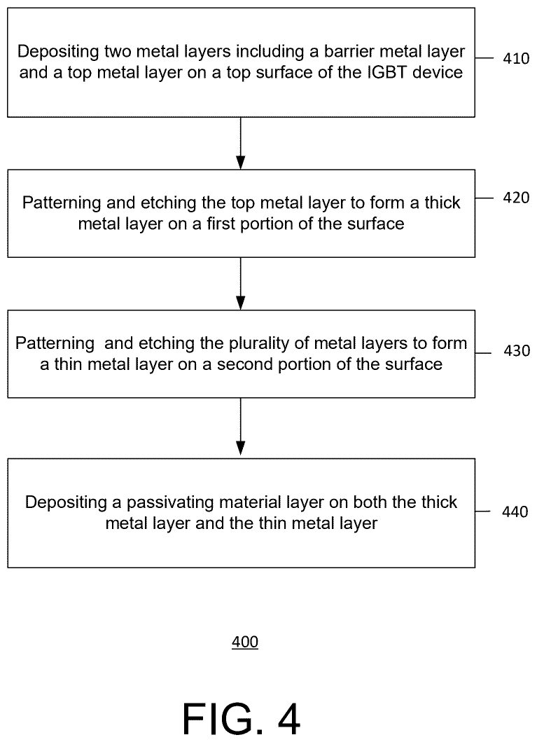

FIG. 4 shows an example method 400 for fabricating a metallization structure on a device surface. The device may, for example, be an IGBT device (e.g., device 100, FIG. 2) fabricated in a semiconductor wafer. As previously discussed with reference to FIG. 2, the device structures (e.g., insulated gate, bipolar transistor, etc.) of device 100 may be fabricated in a semiconductor substrate 110 having a thickness or height T between a top surface TS and a bottom surface BS. The device structures of device 100 may, for example, include a trench capacitor 512, and a p+ doped region 510 (emitter) disposed in a p-doped well 210 at top surface TS. Trench capacitor 512 may form a gate of device 100. A junction termination region 31 may include a plurality of p doped wells (e.g., p-well 312) and a n++ doped well 314 buried under the top surface TS. A strip of gate poly 514 may connect the p+ doped region 510 to a gate runner region (e.g., to metal layer 612).

Device 100 (e.g., an IGBT) may have a top surface with a patterned first dielectric layer (e.g., first dielectric layer 710, a doped oxide film with phosphorus and boron (PSG/BPSG)) and a patterned second dielectric layer (e.g., second dielectric layer 712, a silicon dioxide film) disposed consecutively (one above the other) on portions of the top surface TS to protect the device structures in semiconductor substrate 110. A strip of gate poly 514 may be disposed on a portion of top surface TS and may extend over an edge of first dielectric layer 710. The second dielectric layer 712 may extend over a portion a strip of gate poly 514.

FIG. 4 illustrates an example method 400 for fabricating a metallization structure M2 on a device (e.g., device 100 of FIG. 2).

Method 400 (FIG. 4) includes depositing two metal layers including a barrier metal layer and a top metal layer on a top surface of the IGBT device (step 410). The metal layers may be deposited as blanket layers (i.e., without patterning) on the top surface of the IGBT device. The barrier metal layer may, for example, be Ti/TiN/W and may be less than 0.5 μm in thickness. The top metal layer deposited on top of the barrier metal layer may, for example, be AlCu, AlSi or AlCuSi, and may be between 2.0 and 6 μm in thickness.

Method 400 further includes patterning and etching the top metal layer to form a thick metal layer on a first portion of the surface (step 420). The first metal etching of the top metal layer (e.g., AlCu, AlSi, or AlSiCu) may involve wet etching of the top metal layer. The top metal layer may be patterned and etched to form thick metal layers for all metal layer segments (including, e.g., an emitter metal layer segment (metal layer 610), and a gate runner metal layer segment (e.g., metal layer 612), in metallization structure M2. The first metal etching may involve wet etching which can selectively etch the top metal layer with little or no etching of the (Ti/TiN/W) barrier metal layer.

Method 400 further includes patterning and etching the plurality of metal layers to form a thin metal layer on a second portion of the surface (step 430). The second metal etching may involve wet etching or dry etching the barrier metal layer to define thin metal layer segments (metal layer 614, metal layer 616)) that may form, for example, field or potential plates, or channel stops for the device in metallization structure M2.

Method 400 further includes photolithography and depositing a passivating material layer on both the thick metal layer and the thin metal layer in the metallization structure M2 (step 440). The passivating material may, for example, be a high refractive index nitride (HRN) material.

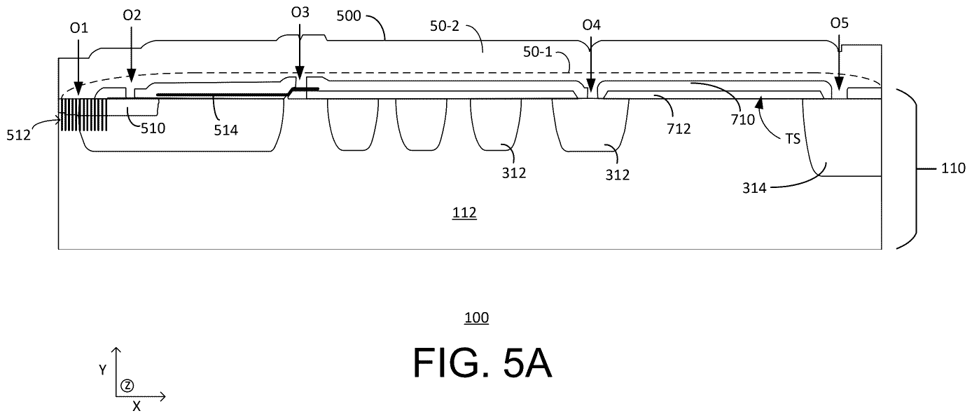

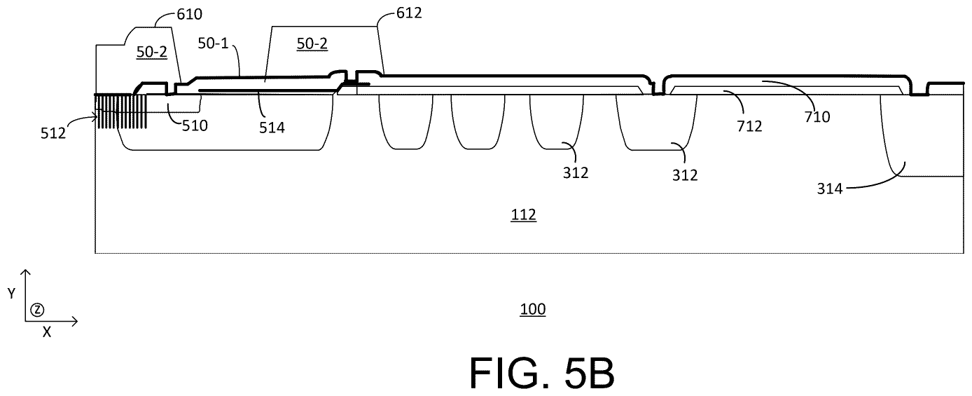

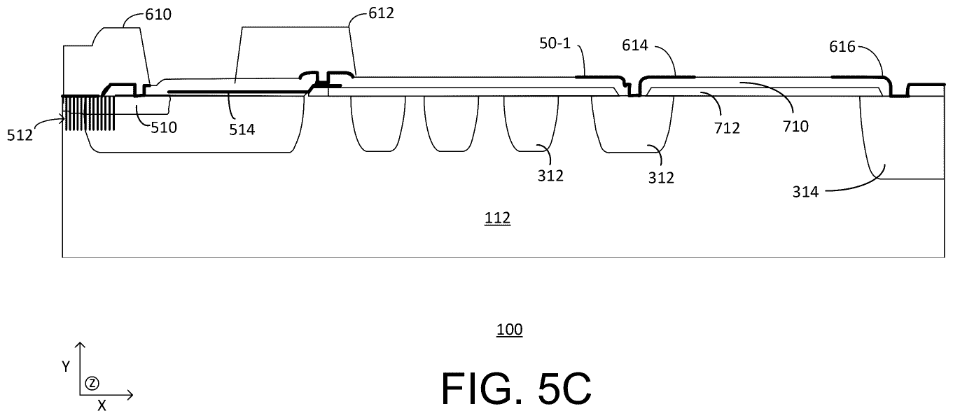

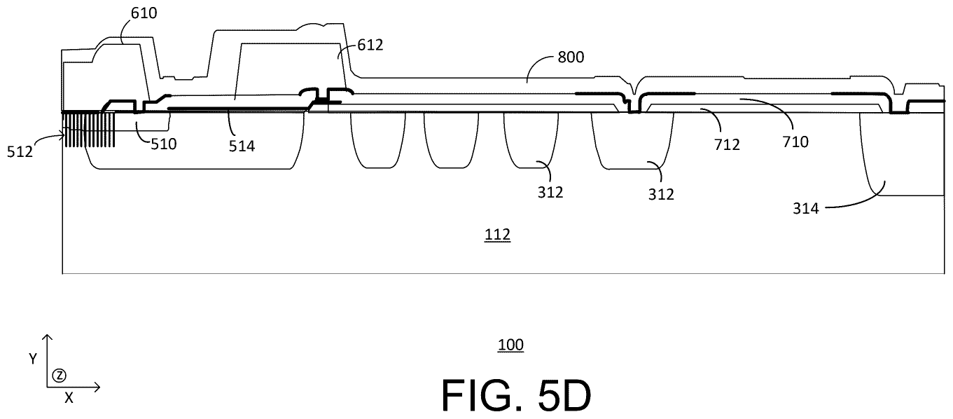

FIGS. 5A through 5D illustrate partial cross-sectional views of a metallization structure on a device at various stages of construction. The device may, for example, be an IGBT device (e.g., device 100, FIG. 2) fabricated on or in a semiconductor substrate 110. Semiconductor substrate 110 may, for example, include the device structures of an IGBT device (e.g., trench capacitor 512, a p+ doped region 510 disposed in a p-doped well 210, a plurality of p doped wells (e.g., p-well 312), n++ doped well 314, etc.) formed at or at about top surface TS, or in body 112 of the substrate. The p+ doped region may for example, serve as an emitter of the bipolar transistor.

Portions of the surface of top surface TS of device 100 may be coated with insulating layers (e.g., a first dielectric layer 710 and a second dielectric layer 712). First dielectric layer 710, may, for example, be an oxide glass film doped with phosphorus and or boron (PSG/BPSG). Second dielectric layer 712 may for example, be a silicon dioxide film. Openings (e.g., opening O1, O2, O3, O4, and O5, etc.) in the first dielectric layer 710 and the second dielectric layer 712 may expose portions of the surface the semiconductor substrate. Elements of metallization structure M2 disposed on the top surface of device 100 may be in contact with the device structures of device 100 formed in the semiconductor substrate through these openings (e.g., opening O1, O2, O3, O4, and O5, etc.)

FIG. 5A shows a cross-sectional view of device 100 with a metal layer 500 deposited on a top surface TS of device 100 at a first stage of fabrication of metallization structure M2 (e.g., after step 410 of method 400). Metal layer 500 may include a first metal layer 50-1 and a second metal layer 50-2. First metal layer 50-1 may be barrier metal layer (e.g., Ti/TiN/W) and may be less than 0.5μm in thickness. Second metal layer 50-2 may, for example, be AlCu, AlSi or AlCuSi, and be between 2.0 and 7.0 μm (e.g., 5 μm) in thickness.

FIG. 5B shows a cross-sectional view of device 100 with after patterning and etching of the second metal layer 50-2 (e.g., after step 420 of method 400). The etching may involve selective wet etching of the second metal layer. The etching top can result in an emitter metal layer segment (metal layer 610), and a gate runner metal layer segment (e.g., metal layer 612). The etching may involve wet etching which can selectively etch the top metal layer with little or no etching of the (Ti/TiN/W) barrier metal layer.

FIG. 5C shows a cross-sectional view of device 100 after patterning and etching of the first metal layer 50-1 (e.g., after step 430 of method 400). The etching the first metal layer 50-1 (which includes tungsten (W)) may involve dry etching. This patterning and etching of the second metal layer can result in formation of field or potential plates (e.g., metal layer 614), or channel stops (e.g., metal layer 616) for the device in metallization structure M2.

FIG. 5D shows a cross-sectional view of device 100 after a passivating dielectric layer (e.g., dielectric layer 800) is deposited on both the thick metal structures and the thin metal structures in the metallization structure. In example implementations, the passivating dielectric layer may, for example, be a silicon oxide layer or a high refractive index silicon nitride (HRN) layer.

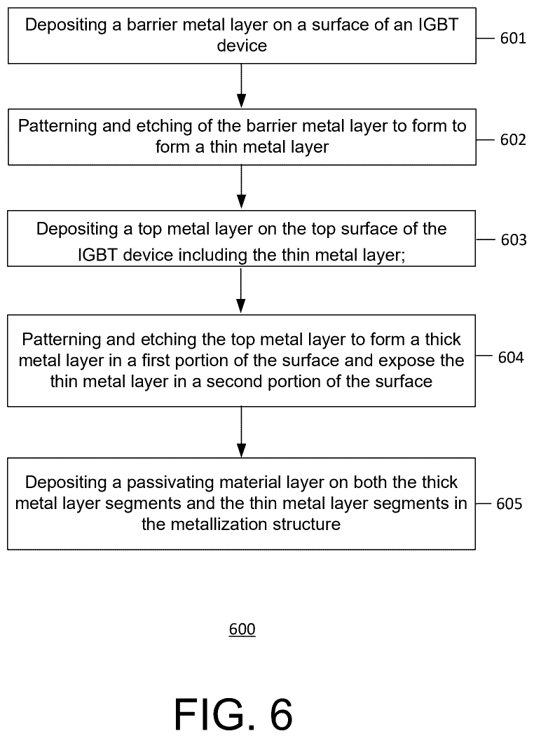

In method 400 described above, the etching steps to form the thick metal layer structures and the thin metal layer structures in the metallization structure occur after both the barrier metal layer and the top metal layer are deposited on the top surface of the IGBT device. In contrast, in another method (e.g., method 600 described below with reference to FIG. 6) an etching step may be carried out after each of the barrier metal layer and the top metal layer are individually deposited (sequentially) on the top surface of the IGBT device.

FIG. 6 illustrates an example method 600 for fabricating a metallization structure M2 on a device (e.g., device 100 of FIG. 2).

Method 600 includes depositing a barrier metal layer on a top surface of the IGBT device (601). The barrier metal layer may for example, be Ti/TiN/W and may be less than 0.5 μm in thickness. Depositing the barrier metal layer may include depositing tungsten (W) plugs along with the Ti/TiN material.

Method 600 further includes a first photolithographic patterning and a first metal etching of the barrier metal layer to form at least a thin metal layer segment in a metallization structure (step 602). The first metal etching may involve dry etching of the barrier metal layer. The barrier metal layer may be patterned and etched to form thin metal layer segments for all structures in metallization structure M2 (including, e.g., an emitter metal layer segment, a gate runner metal layer segment, and junction termination region metal layer segments including segments for filed plates and channel stops).

Method 600 further includes depositing a top metal layer on the top surface of the IGBT device (step 603). The top metal layer may be deposited over the thin metal layer segments formed at step 602 in method 400. The top metal layer may, for example, be AlCu, AlSi or AlCuSi, and may be between 2.0 and 7.0 μm (e.g., 5 μm) in thickness.

Method 600 further includes a second photolithographic patterning and a second metal etching of the top metal layer to form at least a thick metal layer segment in a first portion of the surface and to expose the thin metal layers in a second portion of the surface (604). The second metal etching may involve wet etching of the top metal layer to form selected thick metal layer segments (e.g., emitter metal layer segment (metal layer 610), and gate runner metal layer segment (metal layer 612), and to expose thin metal layers for other metal layer segments (e.g., junction termination region metal layer segments (metal layer 614, metal layer 616) in the metallization structure M2.

Method 600 further includes photolithography and deposition of passivating material on both the thick metal layers segments and the thin metal segments in the metallization structure M2 (step 605). The passivating material may, for example, be a high refractive index nitride (HRN) material.

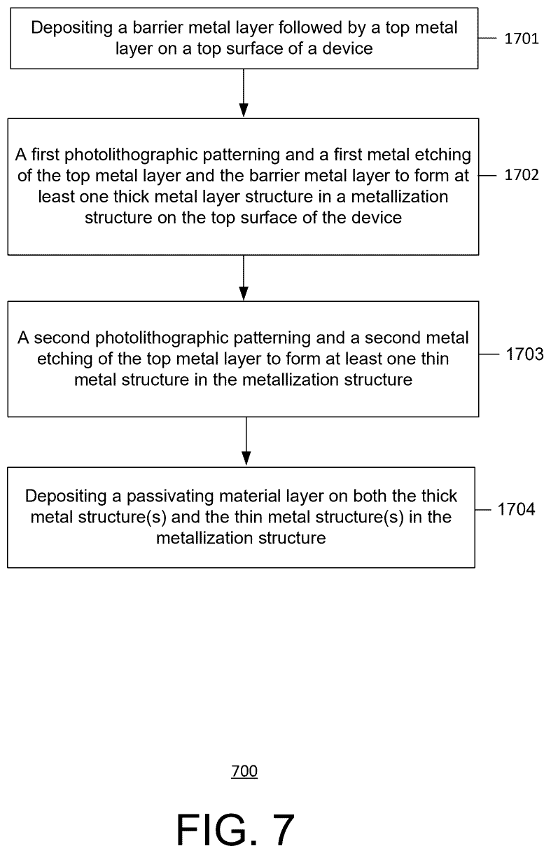

FIG. 7 illustrates yet another example method 700 for fabricating a metallization structure M2 on a device (e.g., device 100 of FIG. 2).

Method 700 includes depositing a barrier metal layer followed by a top metal layer on a top surface of a device (1701). The barrier metal layer may for example, be a stack of Ti/TiN/W layers and may be less than 0.5 μm in thickness. Depositing the barrier metal layer may include depositing tungsten (W) plugs along with the Ti/TiN material. The top metal layer which is deposited on top of the barrier metal layer may include conductive metals (e.g., non-refractory metals) or metal alloys such as AlCu, AlSi or AlCuSi.

Method 700 further includes a first photolithographic patterning and a first metal etching of the top metal layer and the barrier metal layer to form at least one thick metal layer structure in a metallization structure on the top surface of the device (1702). This etching step may use etchants which etch the top metal layer (e.g., AlCu, AlSi or AlCuSi) and also etch the barrier metal layer. This at least one thick metal layer structure may include a segment or portion of the top metal layer disposed on the barrier metal layer (e.g., as in structures 51 and 52 in FIG. 1).

Method 700 further includes a second photolithographic patterning and a second metal etching of the top metal layer to form at least one thin metal structure in the metallization structure (1703). The etching step may use an etchant which stops etching when it reaches the barrier metal layer (e.g., reaches the Ti layer in the barrier metal layer). The at least one thin metal structure may include a segment of the barrier metal layer deposited on the top surface of the device (e.g., as in structures 53, 54, and 55 in FIG. 1).

Method 700 further includes depositing a passivating material layer on both the thick metal structure(s) and the thin metal structure(s) in the metallization structure (1704). The passivating material layer may, for example, be a dielectric material (e.g., an oxide, a nitride, or a high refractive index nitride (HRN), etc.) layer (e.g., layer 60, FIG. 1).

In some example implementations, the dielectric material layer may be a polyimide layer disposed only over the thick metal structure(s) or over both the thick metal structure(s) and the thin metal structure(s).

In the foregoing, the metallization structure is generally described as a metallization structure formed on a surface of an the IGBT device. However, it will be understood that the disclosed metallization structure is not limited to IGBT devices. The disclosed metallization structure may be used for other semiconductor devices (e.g., MOSFETs) and various semiconductor die of any type. One or more semiconductor dies (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a spacer material can be an epoxy, a silicone adhesive, a conductive material, a non-conductive material, an organic material, a semiconductor material, a metal alloy, a metal foam, a phase change material, etc.

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms such as over, above, upper, under, beneath, below, lower, and so forth, are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. A semiconductor device, comprising:
a semiconductor substrate;
a first metal layer having a first thickness disposed on a first portion of a surface of the semiconductor substrate;
a second metal layer having a second thickness disposed on a second portion of the surface of the semiconductor substrate, the first thickness being greater than the second thickness; and
a passivating dielectric material layer disposed over both the first metal layer and the second metal layer.

2. The semiconductor device of claim 1, wherein the second metal layer includes a barrier metal layer made of tungsten.

3. The semiconductor device of claim 2, wherein the first metal layer includes a top metal layer disposed on the barrier metal layer, the top metal layer being made of aluminum-silicon, aluminum-copper, or aluminum-silicon-copper.

4. The semiconductor device of claim 1, wherein the passivating dielectric material layer includes a high refractive index material.

5. The semiconductor device of claim 1, wherein a portion of the first metal layer is coupled to an emitter and/or a gate of the semiconductor device.

6. The semiconductor device of claim 1, wherein a portion of the first metal layer forms a gate runner of the semiconductor device.

7. The semiconductor device of claim 6, wherein a strip of polysilicon connects the gate runner to a gate of the semiconductor device.

8. The semiconductor device of claim 1, wherein the second metal layer extends through, and forms surface field plates in, a junction termination region of the semiconductor device.

9. The semiconductor device of claim 8, wherein the second metal layer is coupled to a p-doped well in the junction termination region.

10. The semiconductor device of claim 1, wherein the first thickness is greater than 1.0 μm, and the second thickness is less than 1.0 μm.

11. The semiconductor device of claim 1, wherein a polyimide layer is either disposed only over the first metal layer or over both the first metal layer and the second metal layer.

12. A method comprising:
depositing a plurality of metal layers including a barrier metal layer and a top metal layer on a surface of a semiconductor device;
patterning and etching the top metal layer to form a thick metal layer on a first portion of the surface;
patterning and etching the plurality of metal layers to form a thin metal layer on a second portion of the surface; and
depositing a passivating material layer on both the thick metal layer and the thin metal layer.

13. The method of claim 12, wherein the barrier metal layer includes a layer made of tungsten, and the top metal layer is made of aluminum-silicon, aluminum-copper, or aluminum-silicon-copper.

14. The method of claim 12, wherein the barrier metal layer is less than 1.0 μm thick and the top metal layer is greater than 1.0 μm thick.

15. The method of claim 12, wherein a first segment of the thick metal layer is coupled to an emitter and/or a gate of the semiconductor device, and a second segments of the thick metal layer forms a gate runner of the semiconductor device.

16. The method of claim 12, wherein a wherein the thin metal layer extends through, and forms surface field plates in, a junction termination region of the semiconductor device.

17. A method comprising:
depositing a barrier metal layer on a surface of a semiconductor device;
patterning and etching the barrier metal layer to form a thin metal layer;
depositing a top metal layer on the surface of the semiconductor device including the thin metal layer;
patterning and etching the top metal layer to form a thick metal layer in a first portion of the surface and expose the thin metal layer in a second portion of the surface; and
depositing a passivating material layer on both the thick metal layer and the thin metal layer.

18. The method of claim 17, wherein the barrier metal layer includes a layer made of tungsten, and the top metal layer is made of aluminum-silicon, aluminum-copper, or aluminum-silicon-copper.

19. The method of claim 17, wherein a first segment of the thick metal layer is coupled to an emitter and/or a gate of the semiconductor device, and a second segment of the thick metal layer forms a gate runner of the semiconductor device.

20. The method of claim 17, wherein the thin metal layer extends through, and forms a surface field plate in, a junction termination region of the semiconductor device.

21. A method comprising:
depositing a barrier metal layer followed by a top metal layer on a top surface of a device;
a first photolithographic patterning and a first metal etching of the top metal layer and the barrier metal layer to form at least one thick metal layer structure including a portion of the top metal layer disposed on the barrier metal layer;
a second photolithographic patterning and a second metal etching of the top metal layer to form at least one thin metal structure including a segment of the barrier metal layer disposed on the top surface of the device; and
depositing a passivating material layer on both the at least one thick metal layer structure and the at least one thin metal structure.

22. The method of claim 21, wherein the barrier metal layer includes a layer of tungsten and is less than 1.0 μm thick.

23. The method of claim 22, wherein the passivating material layer includes an oxide, a nitride, or a high refractive index nitride (HRN) material.
